(19) United States
(12) Patent Application Publication
(10) Pub. No.: US 2004/0140417 A1
(43) Pub. Date: Jul. 22, 2004

(54) Image sensor for confocal microscopy

(75) Inventor: Jacob Karin, Ramat Gan (IL)

Correspondence Address: DR. MARK FRIEDMAN LTD., C/O BILL POLKINGHORN, DISCOVERY DISPATCH, 9003 FLORIN WAY, UPPER MARLBORO, MD, 20772, US

(73) Assignee: Accretech (Israel) Ltd.

(21) Appl. No.: 10/744,017

(22) Filed: Dec. 24, 2003

Related U.S. Application Data
(60) Provisional application No. 60/436,452, filed on Dec. 27, 2002.

(51) Int. Cl. H01L 27/00; H01J 3/14; H01J 5/16

(52) U.S. Cl. 250/208.1; 250/234

(57) ABSTRACT

An image sensor, comprising a substrate and an array of at least twenty radiation sensing regions disposed on the substrate. The sensing regions only have non-sensing regions therebetween. Each sensing region has a maximum dimension which is less than 50 microns. A spacing of the radiation sensing regions is at least 5 times the maximum dimension.

This application claims priority from Co-pending U.S. Provisional Application No. 60/436,452 filed 27′ December 2002.

### FIELD AND BACKGROUND OF THE INVENTION

The present invention relates to confocal microscopy and, in particular, it concerns a sensor system for confocal microscopy.

By way of introduction, in a confocal microscope pinhole arrays are placed after the light source and just before the light sensor. This arrangement provides numerous advantages, especially by providing a reduced depth of focus that allows viewing a specific cross-section of a sample, at a specific height in the sample. Traditionally, a standard image sensor is used, such as a CCD or CMOS sensor, and a pinhole array is placed in the incoming light path adjacent to the sensor.

CMOS light sensors are made of light sensitive cells embedded in a Silicon chip. Each of the light sensitive cells has its own address that provides individual reading capabilities. The technology of CMOS light sensors has developed in the recent years to provide high-definition video cameras in full color. The industry strives to achieve the highest possible cell density in such chips, since this translates to higher image resolution, reduced chip size and thereby reduced cost, higher sensitivity and speed. CMOS image sensors can reach data streaming of 10 Mega-pixels per second at a resolution of 10 bits per pixel, resulting in a 100 Gigabit per second data rate. The highest clock rate that can be obtained from a single wire output pin is 100 Mega Hertz therefore resulting in a need for 1000 output pins for the data bus, thus prohibiting the packaging of such a chip.

In a confocal system, most of the CMOS sensor is not utilized for sensing incoming light due to the pinhole array and the discrete illumination points inherent in a confocal system.

There is therefore a need for a low-cost, high-speed sensor for use in confocal microscopy.

### SUMMARY OF THE INVENTION

The present invention is a confocal image sensor construction and method of operation thereof.

According to the teachings of the present invention there is provided, an image sensor, comprising: (a) a substrate; and (b) an array of at least 20 radiation sensing regions disposed on the substrate, the sensing regions only having non-sensing regions therebetween, each of the sensing regions having a maximum dimension, the maximum dimension being less than 50 microns, a spacing of the radiation sensing regions being at least 5 times the maximum dimension.

According to a further feature of the present invention, there is also provided a plurality of signal processing circuits disposed on the substrate, the signal processing circuits being interspersed with the radiation sensing regions, the signal processing circuits configured for processing signals from the radiation sensing regions.

According to a further feature of the present invention, each of the signal-processing circuits is uniquely associated with one of the radiation sensing regions.

According to a further feature of the present invention, the signal processing circuits are arranged on the substrate such that, signals from the radiation sensing regions travel less than 100 microns in order to arrive at one of the signal processing circuits.

According to a further feature of the present invention, the signal processing circuits are configured for amplifying the signals from the radiation sensing regions.

According to a further feature of the present invention, the signal processing circuits are further configured for filtering the signals.

According to a further feature of the present invention, the signal processing circuits are further configured for converting the signals from the radiation sensing regions from analogue signals to digital signals.

According to a further feature of the present invention, the signal processing circuits are further configured for compressing the digital signals.

According to a further feature of the present invention, the signal processing circuits are further configured for data format rearrangement of the digital signals.

According to a further feature of the present invention, the signal processing circuits are further configured for filtering the digital signals.

According to a further feature of the present invention, there is also provided a plurality of optical transducers and an optical communication link, the optical transducers being disposed on the substrate, the optical transducers being operationally connected to the optical communication link and the radiation sensing regions, the optical transducers being configured for converting electrical signals from the radiation sensing regions into optical signals in preparation for transmission through the optical communication link to an external processor.

According to a further feature of the present invention, there is also provided an optical communication link operationally connected to the radiation sensing regions, the optical communication link being configured for transmitting, to an external processor, optical signals indicative of radiation detected by the radiation sensing regions.

According to the teachings of the present invention there is also provided a confocal microscope system for scanning a sample, comprising: (a) a confocal source arrangement configured so as to define pinhole sources for directing radiation to a plurality of points of the sample; and (b) a confocal image sensor configured for detecting radiation reflected from the sample, the image sensor having a substrate and an array of at least 20 radiation sensing regions disposed on the substrate, the sensing regions only having non-sensing regions therebetween, each of the sensing regions having a maximum dimension, the maximum dimension being less than 50 microns, a spacing of the radiation sensing regions being at least 5 times the maximum dimension, the radiation sensing regions being located so as to define pinhole sensors conjugate with the pinhole sources of the confocal source arrangement.

According to a further feature of the present invention, there is also provided a plurality of signal processing circuits disposed on the substrate, the signal processing circuits being interspersed with the radiation sensing regions, the signal processing circuits configured for processing signals from the radiation sensing regions.

According to a further feature of the present invention, each of the signal-processing circuits is uniquely associated with one of the radiation sensing regions.

According to a further feature of the present invention, the signal processing circuits are arranged on the substrate such that, signals from the radiation sensing regions travel less than 100 microns in order to arrive at one of the signal processing circuits.

According to a further feature of the present invention, the signal processing circuits are configured for amplifying the signals from the radiation sensing regions.

According to a further feature of the present invention, the signal processing circuits are further configured for filtering the signals.

According to a further feature of the present invention, the signal processing circuits are further configured for converting the signals from the radiation sensing regions from analogue signals to digital signals.

According to a further feature of the present invention, the signal processing circuits are further configured for compressing the digital signals.

According to a further feature of the present invention, the signal processing circuits are further configured for data format rearrangement of the digital signals.

According to a further feature of the present invention, the signal processing circuits are further configured for filtering the digital signals.

According to a further feature of the present invention, there is also provided a plurality of optical transducers and an optical communication link, the optical transducers being disposed on the substrate, the optical transducers being operationally connected to the optical communication link and the radiation sensing regions, the optical transducers being configured for converting electrical signals from the radiation sensing regions into optical signals in preparation for transmission through the optical communication link to an external processor.

According to a further feature of the present invention, there is also provided an optical communication link operationally connected to the radiation sensing regions, the optical communication link being configured for transmitting, to an external processor, optical signals indicative of radiation detected by the radiation sensing regions.

### BRIEF DESCRIPTION OF THE DRAWINGS

The invention is herein described, by way of example only, with reference to the accompanying drawings, wherein:

FIG. 1 is a schematic view of a confocal microscope system having an image sensor that is constructed and operable in accordance with a preferred embodiment of the invention; and

FIG. 2 is a schematic plan view of the image sensor of FIG. 1.

### DESCRIPTION OF THE PREFERRED EMBODIMENTS

The present invention is a confocal image sensor construction and method of operation thereof.

The principles and operation of a confocal image sensor according to the present invention may be better understood with reference to the drawings and the accompanying description.

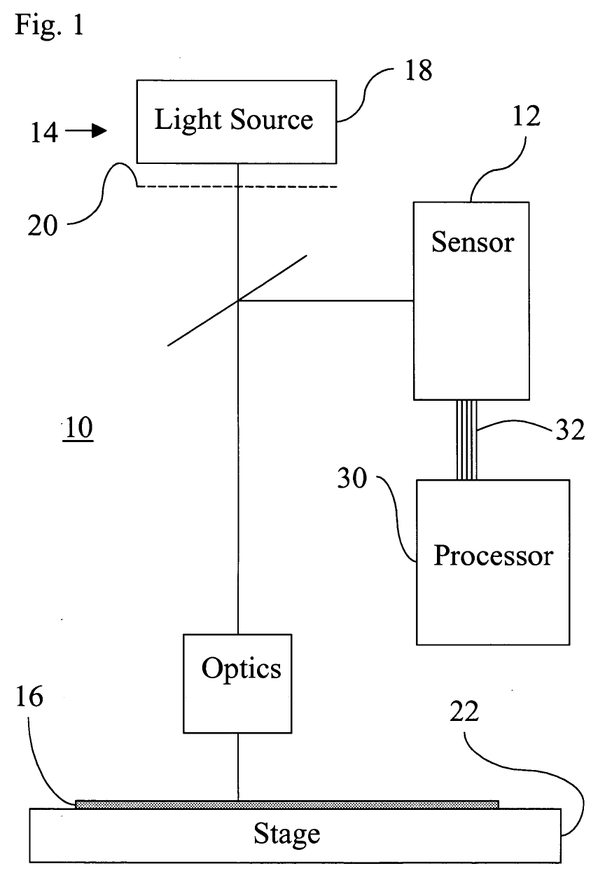

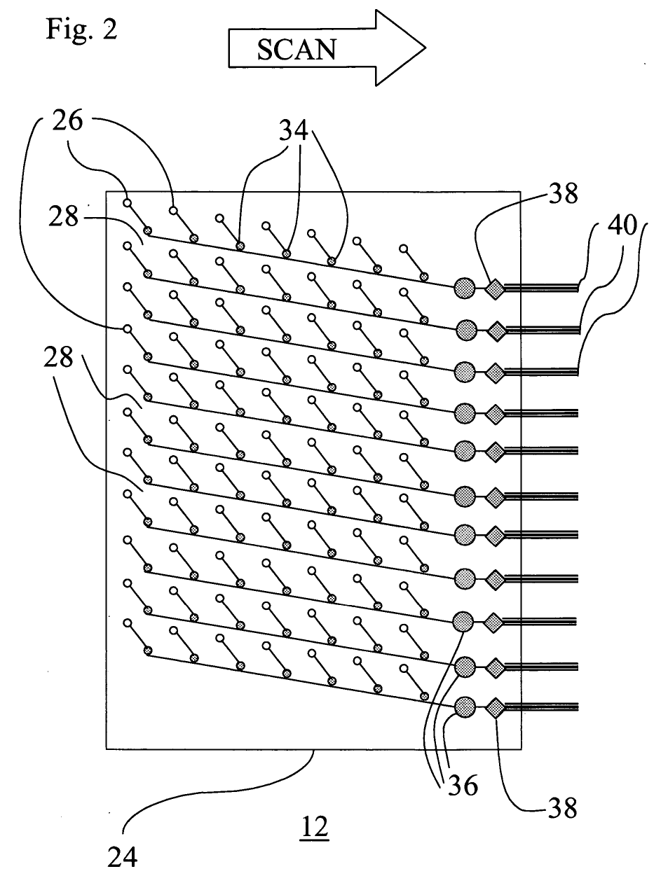

Reference is now made to FIGS. 1 and 2. FIG. 1 is a schematic view of a confocal microscope system 10 having an image sensor 12 that is constructed and operable in accordance with a preferred embodiment of the invention. FIG. 2 is a schematic plan view of image sensor 12 of FIG. 1. Confocal microscope system 10 includes a confocal source arrangement 14. Confocal source arrangement 14 includes a radiation source 18 and a pinhole array 20 thereby configuring confocal source arrangement 14 so as to define pinhole sources for directing radiation to a plurality of points of a sample 16, thereby illuminating these points. The term illumination is defined herein to include illumination with radiation other than visible light. The radiation is typically visible light or Ultraviolet light. The term “points of sample 16” is used for convenience to define the discrete regions illuminated by confocal source arrangement 14. Sample 16 is mounted on a stage 22. Confocal microscope system 10 also includes image sensor 12 and a processor 30. Image sensor 12 is configured for detecting radiation reflected from sample 16. Processor 30 is configured for processing data received from image sensor 12. Image sensor 12 and processor 30 are operationally connected via an optical communication link 32. Image sensor 12 includes a substrate 24 and an array of 20 or more, typically 200, radiation sensing regions 26 disposed on substrate 24. Image sensor 12 is typically formed by disposing radiation-sensing regions 26 on to substrate 24. Substrate 24 is generally a silicon chip. Radiation sensing regions 26 only have non-sensing regions 28 therebetween. The term “non-sensing regions” is defined herein to exclude sensing regions sensing the same type of radiation as radiation sensing regions 26 from the same incident directions that radiation sensing regions 26 are sensing. For example, non-sensing regions 28 may include other optical sensors and sources used in communication between image sensor 12 and processor 30 via optical communication link 32, as will be described in more detail below. Additionally, non-sensing regions 28 typically include electronic circuits used to process signals generated by radiation sensing regions 26, as will be described in more detail below. It should be noted that non-sensing regions 28 are generally not separate unconnected regions. Non-sensing regions 28 are generally interconnected forming one large region having radiation sensing regions 26 interspersed in this one large region. Each radiation-sensing region 26 has a maximum dimension. This maximum dimension is less than 50 microns, typically 5 microns and less. The spacing of radiation sensing regions 26 is at least 5 times, typically ten times, this maximum dimension, in all directions. The spacing of radiation sensing regions 26 is defined as the distance between same points in adjacent radiation sensing regions 26.

Radiation sensing regions 26 are located so as to define pinhole sensors conjugate with the illumination pinholes of pinhole array 20 of confocal source arrangement 14. That is, radiation sensing regions 26 are located on image sensor 12 and image sensor 12 is positioned with respect to the incident radiation, such that radiation sensing regions 26 define pinhole sensors conjugate with the illumination points of the sample. The term “pinhole sensors conjugate with the illumination points” is defined herein as, radiation sensing regions 26 are located at the location of pinholes of a pinhole array of a prior art confocal microscope, such that radiation sensing regions 26 are conjugate with the illumination points on sample 16, thereby selectively sensing radiation reflected from the corresponding illumination points of sample 16.

Therefore, image sensor 12 performs the same function as a prior art confocal pinhole array and sensor arrangement. However, image sensor 12 does not require a pinhole array. Additionally, most of radiation-sensing regions 26 are used in detecting incident radiation. Image sensor 12 is typically cheaper to produce than a prior art image sensor which is partially blindfolded by a pinhole array.

There are additional advantages of image sensor 12. First, the space available between radiation sensing regions 26 is used to host additional electronic circuitry that supports faster data retrieval, enabling quicker scanning with image sensor 12, as will be described in more detail below. Second, it is well known in the art of electronic chip design that high speed equals excessive energy consumption that causes heating of the silicon chip. The non-sensing regions 28 between the radiation sensing regions 26 reduces this problem by providing space between the “fast elements” on the chip allowing for better heat dissipation.

Image sensor 12 includes a plurality of signal processing circuits 34 disposed on substrate 24 interspersed with radiation sensing regions 26. Signal processing circuits 34 are configured for processing signals from radiation sensing regions 26. The term “signal” is defined herein to include analogue signals and digital data signals. Pre-processing of the signals from radiation sensing regions 26 at a close proximity to radiation sensing regions 26 is another factor that improves both speed and quality of the received image. Therefore, signal processing circuits 34 are arranged on substrate 24 such that, signals from radiation sensing regions 26 travel less than 100 microns in order to arrive at a signal processing circuits 34. Preferably, each signal processing circuit 34 is uniquely associated with one of radiation sensing regions 26 in order to provide pre-processing as close to each radiation sensing region 26 as possible. However, it will be appreciated by those ordinarily skilled in the art that one signal processing circuit 34 can perform preprocessing for more than one radiation-sensing region 26. Signal processing circuits 34 are configured for amplifying and filtering the signals from radiation sensing regions 26. Filtering includes removing parts of the data that are not important or even disturbing, such as very high frequencies that are not relevant to the radiation being detected or noise. Signal processing circuits 34 are further configured for converting the signals from analogue signals to digital signals. Signal processing circuits 34 are further configured for compressing the digital signals (with or without loss of some data) and data format rearrangement of the digital signals, for example, but not limited to, converting digital data from an 8 bit format to 64 bit or 128 bit formats that are more suitable for data transmission.

As described above, one of the shortcomings of prior-art image sensors is that the slow speed of handling data produced by the image sensors. Therefore, image sensor 12 includes optical communication link 32 for downloading data from image sensor 12 to processor 30. Optical communication link 32 is operationally connected to radiation sensing regions 26. Optical communication link 32 is configured for transmitting, to processor 30, optical signals indicative of radiation detected by radiation sensing regions 26. Optical communication link 32 is typically an optical fiber link including a plurality of optical fibers 40. However, it will be appreciated by those ordinarily skilled in the art that that optical communication link 32 can be an optical link through air without optical fibers. The term “optical” is defined herein to include visible light Ultraviolet and Infrared radiation. Optical communication link 32 provides a data transfer link at a rate which is not achievable via traditional wiring methods. In order to prepare data processed by signal processing circuits 34 for transmission through optical communication link 32, image sensor 12 also includes a plurality of signal processing circuits 36 and a plurality of optical transducers 38. Signal processing circuits 36 and optical transducers 38 are disposed on substrate 24. Each signal processing circuit 36 is electrically connected to a group of signal processing circuits 34 and one optical transducer 38. Each optical transducer 38 is operationally connected to one optical fiber 40. Each signal processing circuit 36 receives data processed by a group of signal processing circuits 34. Signal processing circuits 36 format the electrical signals received from signal processing circuits 34 into a format suitable for optical transducers 38 to produce optical signals for transmission. Optical transducers 38 convert the electrical signals produced by signal processing circuits 36 into optical signals in preparation for transmission through optical communication link 32 to processor 30. It will be appreciated by those ordinarily skilled in the art that some of the above preprocessing functions, such as amplification, can be performed by signal processing circuit 34, while other preprocessing functions, such as data format rearrangement, can be performed by signal processing circuits 36. By way of example, when image sensor 12 has two hundred radiation sensing regions 26 and each cell is sampled at 50 MegaHertz with a resolution of 6 to 8 bits, ten signal processing circuits 36, ten optical transducers 38 and ten optical fibers 40 are typically required. It will be appreciated by those ordinarily skilled in the art that optical communication link 32 can be bi-directional in order to perform additional functions such as data confirmation.

It will be appreciated by persons skilled in the art that the present invention is not limited to what has been particularly shown and described hereinabove. Rather, the scope of the present invention includes both combinations and sub-combinations of the various features described hereinabove, as well as variations and modifications thereof that are not in the prior art which would occur to persons skilled in the art upon reading the foregoing description.

What is claimed is:

1. An image sensor, comprising:
(a) a substrate; and
(b) an array of at least 20 radiation sensing regions disposed on said substrate, said sensing regions only having non-sensing regions therebetween, each of said sensing regions having a maximum dimension, said maximum dimension being less than 50 microns, a spacing of said radiation sensing regions being at least 5 times said maximum dimension.

2. The image sensor of claim 1, further comprising a plurality of signal processing circuits disposed on said substrate, said signal processing circuits being interspersed with said radiation sensing regions, said signal processing circuits configured for processing signals from said radiation sensing regions.

3. The image sensor of claim 2, wherein each of said signal-processing circuits is uniquely associated with one of said radiation sensing regions.

4. The image sensor of claim 2, wherein said signal processing circuits are arranged on said substrate such that, signals from said radiation sensing regions travel less than 100 microns in order to arrive at one of said signal processing circuits.

5. The image sensor of claim 2, wherein said signal processing circuits are configured for amplifying said signals from said radiation sensing regions.

6. The image sensor of claim 5, wherein said signal processing circuits are further configured for filtering said signals.

7. The image sensor of claim 5, wherein said signal processing circuits are further configured for converting said signals from said radiation sensing regions from analogue signals to digital signals.

8. The image sensor of claim 7, wherein said signal processing circuits are further configured for compressing said digital signals.

9. The image sensor of claim 7, wherein said signal processing circuits are further configured for data format rearrangement of said digital signals.

10. The image sensor of claim 7, wherein said signal processing circuits are further configured for filtering said digital signals.

11. The image sensor of claim 1, further comprising a plurality of optical transducers and an optical communication link, said optical transducers being disposed on said substrate, said optical transducers being operationally connected to said optical communication link and said radiation sensing regions, said optical transducers being configured for converting electrical signals from said radiation sensing regions into optical signals in preparation for transmission through said optical communication link to an external processor.

12. The image sensor of claim 1, further comprising an optical communication link operationally connected to said radiation sensing regions, said optical communication link being configured for transmitting, to an external processor, optical signals indicative of radiation detected by said radiation sensing regions.

13. A confocal microscope system for scanning a sample, comprising:
(a) a confocal source arrangement configured so as to define pinhole sources for directing radiation to a plurality of points of the sample; and
(b) a confocal image sensor configured for detecting radiation reflected from the sample, said image sensor having a substrate and an array of at least 20 radiation sensing regions disposed on said substrate, said sensing regions only having non-sensing regions therebetween, each of said sensing regions having a maximum dimension, said maximum dimension being less than 50 microns, a spacing of said radiation sensing regions being at least 5 times said maximum dimension, said radiation sensing regions being located so as to define pinhole sensors conjugate with said pinhole sources of said confocal source arrangement.

14. The system of claim 13, further comprising a plurality of signal processing circuits disposed on said substrate, said signal processing circuits being interspersed with said radiation sensing regions, said signal processing circuits configured for processing signals from said radiation sensing regions.

15. The system of claim 14, wherein each of said signal-processing circuits is uniquely associated with one of said radiation sensing regions.

16. The system of claim 14, wherein said signal processing circuits are arranged on said substrate such that, signals from said radiation sensing regions travel less than 100 microns in order to arrive at one of said signal processing circuits.

17. The system of claim 14, wherein said signal processing circuits are configured for amplifying said signals from said radiation sensing regions.

18. The system of claim 17, wherein said signal processing circuits are further configured for filtering said signals.

19. The system of claim 17, wherein said signal processing circuits are further configured for converting said signals from said radiation sensing regions from analogue signals to digital signals.

20. The system of claim 19, wherein said signal processing circuits are further configured for compressing said digital signals.

21. The system of claim 19, wherein said signal processing circuits are further configured for data format rearrangement of said digital signals.

22. The system of claim 19, wherein said signal processing circuits are further configured for filtering said digital signals.

23. The system of claim 13, further comprising a plurality of optical transducers and an optical communication link, said optical transducers being disposed on said substrate, said optical transducers being operationally connected to said optical communication link and said radiation sensing regions, said optical transducers being configured for converting electrical signals from said radiation sensing regions into optical signals in preparation for transmission through said optical communication link to an external processor.

24. The system of claim 13, further comprising an optical communication link operationally connected to said radiation sensing regions, said optical communication link being configured for transmitting, to an external processor, optical signals indicative of radiation detected by said radiation sensing regions.
